(19) United States
(12) Patent Application Publication
(10) Pub. No.: US 2009/0001506 A1
(43) Pub. Date: Jan. 1, 2009

(54) DUAL STRESS LINER EFUSE

(76) Inventors: Deok-Kee Kim, Bedford Hills, NY (US); Haining S. Yang, Wappingers Falls, NY (US)

Correspondence Address: FREDERICK W. GIBB, III;Gibb & Rahman, LLC, 2568-A RIVA ROAD, SUITE 304, ANNAPOLIS, MD, 21401, US

(21) Appl. No.: 11/771,172

(22) Filed: Jun. 29, 2007

(51) Int. Cl. H01L 23/52; H01L 21/44

(52) U.S. Cl. 257/529; 438/601; 257/E23.149; 257/E21.476

(57) ABSTRACT

A semiconductor fuse structure comprises an anode connected to a first end of a fuse link, a cathode connected to a second end of the fuse link opposite the first end of the fuse link, a compressive (nitride) liner covering the anode, and a tensile (nitride) liner covering the cathode. The compressive liner and the tensile liner are positioned to cause a net stress gradient between the cathode and the anode, wherein the net stress gradient promotes electromigration from the cathode and the fuse link to the anode.

### BACKGROUND AND SUMMARY

The embodiments of the invention generally relate to semiconductor fuses and more particularly to a semiconductor fuse that includes a tensile stress liner over the cathode and a compressive stress liner over the anode to promote electromigration from the cathode to the anode.

Atomic movements in a confined conductor of a semiconductor fuse due to electromigration can cause tensile stress near the cathode and compressive stress near the anode. The tensile stress at the cathode forms voids and the compressive stress at the anode forms hillocks. The surrounding material around the conductor usually opposes the electromigration and causes a stress gradient in the conductor line. For a more complete discussion of such phenomenon, see Korhonen et al, “Stress evolution due to electromigration in confined metal lines,” Journal of Applied Physics 73, 3790 (1993).

In order to enhance the electromigration in the eFUSE structure, the present invention uses a dual stress nitride liner to alleviate the stress gradient or to create a favorable stress condition and hence enhance the electromigration. To the contrary, conventional structures use only a single CA nitride liner. For example, see U.S. Pat. No. 6,624,499 (incorporated herein by reference) which describes fuse programming by electromigration of silicided polysilicon on STI oxide. Similarly, U.S. Pat. No. 5,708,291 (incorporated herein by reference) describes fuse programming by silicide agglomeration on polysilicon on top of oxide. Also, U.S. Pat. No. 6,323,535 (incorporated herein by reference) discloses fuse programming enhancement using different dopant types among cathode, anode, and fuse link.

More specifically, the present disclosure provides a new semiconductor fuse structure that comprises an anode connected to a first end of a fuse link, a cathode connected to a second end of the fuse link opposite the first end of the fuse link, a compressive (nitride) liner covering the anode, and a tensile (nitride) liner covering the cathode. The compressive liner and the tensile liner are positioned to cause a net stress gradient between the cathode and the fuse link, wherein the net stress gradient promotes electromigration from the cathode and the fuse link to the anode.

Another embodiment herein provides a compressive liner covering the anode and the first half of the fuse link, and a tensile liner covering the cathode and the second half of the fuse link. In this embodiment, the compressive liner and the tensile liner are positioned to cause a net stress gradient between 1) the cathode and the second half of the fuse link and 2) the anode and the first half of the fuse link, wherein the net stress gradient promotes electromigration from the cathode and the second half of the fuse link to the anode and the first half of the fuse link.

These and other aspects of the embodiments of the invention will be better appreciated and understood when considered in conjunction with the following description and the accompanying drawings. It should be understood, however, that the following descriptions, while indicating embodiments of the invention and numerous specific details thereof, are given by way of illustration and not of limitation. Many changes and modifications may be made within the scope of the embodiments of the invention without departing from the spirit thereof, and the embodiments of the invention include all such modifications.

### BRIEF DESCRIPTION OF THE DRAWINGS

The embodiments of the invention will be better understood from the following detailed description with reference to the drawings, in which:

FIG. 1 is a schematic top-view diagram of a fuse structure according to embodiments herein; and

FIG. 2 is a schematic top-view diagram of a fuse structure according to embodiments herein.

### DETAILED DESCRIPTION OF EMBODIMENTS

The embodiments of the invention and the various features and advantageous details thereof are explained more fully with reference to the non-limiting embodiments that are illustrated in the accompanying drawings and detailed in the following description. It should be noted that the features illustrated in the drawings are not necessarily drawn to scale. Descriptions of well-known components and processing techniques are omitted so as to not unnecessarily obscure the embodiments of the invention. The examples used herein are intended merely to facilitate an understanding of ways in which the embodiments of the invention may be practiced and to further enable those of skill in the art to practice the embodiments of the invention. Accordingly, the examples should not be construed as limiting the scope of the embodiments of the invention.

As mentioned above, atomic movements in a confined conductor of a semiconductor fuse due to electromigration can cause tensile stress near the cathode and compressive stress near the anode. The tensile stress at the cathode forms voids and the compressive stress at the anode forms hillocks.

In order to address this situation, this invention uses a first stressor, such as any stress liner (e.g., tensile stress nitride liner) near the cathode and second stressor (e.g., compressive nitride liner) near the anode to reduce back diffusion due to back stress and, hence, to enhance the electromigration. While compressive and tensile nitride liners are mentioned in examples herein, any type of stress liner can be used with embodiments herein so long as a stress gradient exists between the first stress liner and the second stress liner that will enhance electromigration from the cathode to the anode. Thus, with the inventive structure, during electromigration, a less compressive stress develops near the anode and a less tensile stress develops near the cathode as material electromigrates from the cathode to the anode. In the conventional structures, as the electromigration occurs from the cathode to anode, a large stress gradient develops, which causes electromigration to stop when the stress gradient reaches a critical value (back-stress). In the present invention, a less compressive stress develops near the anode and a less tensile stress develops (a less stress gradient develops), which causes electromigration to occur easier and causes the final resistance of the fuse higher. This also provides a higher post resistance than conventional structures which allows easier sensing by the enhanced electromigration. This allows the sensing circuit to be very simple and makes the programming transistor smaller.

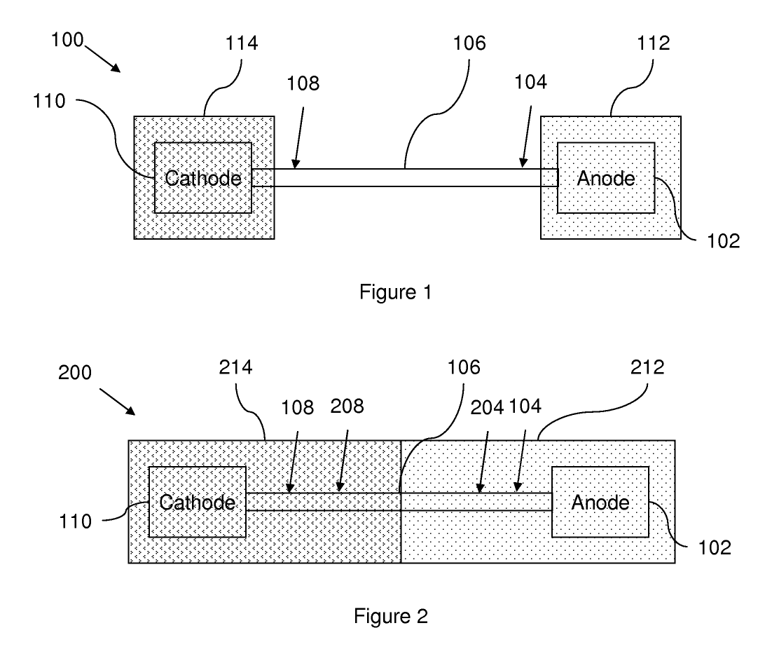

More specifically, as shown in FIG. 1, the present disclosure provides a new semiconductor fuse structure 100 that comprises an anode 102 connected to a first end 104 of a fuse link 106, a cathode 110 connected to a second end 108 of the fuse link 106 opposite the first end 104 of the fuse link 106, a compressive (nitride) liner 112 covering the anode 102, and a tensile (nitride) liner 114 covering the cathode 110. The compressive liner over the anode causes tensile stress in the anode (silicided polysilicon) and the tensile liner over the cathode causes compressive stress in the cathode (silicided polysilicon).

The compressive liner 112 and the tensile liner 114 are positioned to cause a net stress gradient between the cathode 110 and the fuse link 106, wherein the net stress gradient promotes electromigration from the cathode 110 and the fuse link 106 to the anode 102.

Thus, the tensile nitride liners 114 gives compressive stress for silicide and polysilicon fuse structures and the compressive nitride liner 112 gives tensile stress for silicide and polysilicon fuse structures. This causes a net stress gradient between the cathode 110 and the anode 102, which helps electromigration from the cathode 110 to the fuse link 106 and the anode 102.

Another embodiment 200, shown in FIG. 2, provides a compressive liner 212 covering the anode 102 and the first half 204 of the fuse link 106, and a tensile liner 214 covering the cathode 110 and the second half 208 of the fuse link 106. In this embodiment, the compressive liner 212 and the tensile liner 214 are positioned to cause a net stress gradient between 1) the cathode 110 and the second half 208 of the fuse link 106 and 2) the anode 102 and the first half 204 of the fuse link 106, wherein the net stress gradient promotes electromigration from the cathode 110 and the second half 208 of the fuse link 106 to the anode 102 and the first half 204 of the fuse link 106.

Thus, in this embodiment, the cathode 110 and half 204 of the fuse link 106 in contact with the anode 102 are covered with compressive nitride 212. This will cause a net stress gradient between the left half (cathode half) of the fuse structure and the right half (anode half) of the fuse structure, which helps electromigration of silicide from the left half to the right half of the fuse structure and yields improved post programming resistance and gives better sense margin.

The methods, materials, etc. used to form semiconductor fuse structures having anodes, cathodes, fuse links and other accompanying structures are well-known to those ordinarily skilled in the art (for example see U.S. Patent Publications 2007/0120218 and 2007/0099326 incorporated herein by reference) and the details of such processes and materials are not discussed herein to focus the reader on the salient aspects of the claimed invention. Similarly, the methods, materials, etc. used to create compressive and tensile stress layers are well-known to those ordinarily skilled in the art (for example see U.S. Patent Publications 2006/0163685 and 2005/0156268, incorporated herein by reference) and the details of such processes and materials are not discussed herein to focus the reader on the salient aspects of the claimed invention.

The foregoing description of the specific embodiments will so fully reveal the general nature of the invention that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments of the invention have been described in terms of embodiments, those skilled in the art will recognize that the embodiments of the invention can be practiced with modification within the spirit and scope of the appended claims.

What is claimed is:

1. A semiconductor fuse structure comprising:
a fuse link;
an anode connected to a first end of said fuse link;
a cathode connected to a second end of said fuse link opposite said first end of said fuse link;
a first stressor on said anode; and
a second stressor on said cathode,
wherein a stress gradient exists between said first stressor and said second stressor.

2. The structure according to claim 1, wherein said first stressor and said second stressor comprise a stress inducing film.

3. The structure according to claim 1, wherein said first stressor and said second stressor are positioned to cause a net stress gradient between said cathode and said fuse link, wherein said net stress gradient promotes electromigration from said cathode and said fuse link to said anode.

4. A semiconductor fuse structure comprising:
a fuse link comprising a first portion and a second portion;
an anode connected to a first portion of said fuse link;
a cathode connected to a second portion of said fuse link opposite said first end of said fuse link;
a compressive liner covering said anode and said first portion of said fuse link; and
a tensile liner covering said cathode and said second portion of said fuse link.

5. The structure according to claim 4, wherein said compressive liner comprises a compressive nitride liner and said tensile liner comprises a tensile nitride liner.

6. The structure according to claim 4, wherein said compressive liner and said tensile liner are positioned to cause a net stress gradient between 1) said cathode and said second portion of said fuse link and 2) said anode and said first portion of said fuse link, wherein said net stress gradient promotes electromigration from said cathode and said second half of said fuse link to said anode and said first portion of said fuse link.

7. A method of forming a fuse with a stress gradient comprising:
forming an electromigration fuse that comprises a cathode, an anode, and a fuse link; and
forming a stressor on the said electromigration fuse to create a stress gradient across the cathode, anode, and fuse link.

8. The method in claim 7, wherein said forming a stressor comprises:
depositing a tensile liner over a fuse region;
removing the tensile liner from a first portion of said fuse region;
depositing a compressive liner over said fuse region; and
removing a compressive liner from a second portion of said fuse region.
